(19) United States
(12) Patent Application Publication
(10) Pub. No.: US 2013/0158901 A1
(43) Pub. Date: Jun. 20, 2013

(54) Method and System for Detecting Unbalance in Power Grids

(71) Applicants: Zafer Sahinoglu, Cambridge, MA (US); Ming Sun, San Jose, CA (US); Koon Hoo Teo, Lexington, MA (US)

(72) Inventors: Zafer Sahinoglu, Cambridge, MA (US); Ming Sun, San Jose, CA (US); Koon Hoo Teo, Lexington, MA (US)

(21) Appl. No.: 13/329,720

(22) Filed: Dec. 19, 2011

(51) Int. Cl. G06F 17/18; G01R 31/00; G01R 21/06

(52) U.S. Cl. 702/58; 702/60

(57) ABSTRACT

A method for detecting unbalance in a 3-phase voltage signal includes sampling the signal over an observation widow to determine a set of observations, and detecting the unbalance of the signal based on a probability density function (pdf) of the set of observations.

### FIELD OF THE INVENTION

This invention relates generally to electric power grids, and in particular to detecting unbalance in a 3-phase voltage signal in the power grids.

### BACKGROUND OF THE INVENTION

Synchronization in an electric power grid is important to control the operation of the grid when distributed power generators are connected to the grid. The synchronization includes determining an angle of 3-phase voltage signals in the grid. Usually, the voltage signal deviates from the ideal condition and is distorted due to, e.g., additive noise, frequency variation, voltage unbalance, and harmonic components. Therefore, the unbalance impacts accurate synchronization of the phases. In presence of the unbalance, the three-phase voltage signal can be decomposed into positive, negative and zero sequences.

The unbalance of the signal may take place in amplitude, initial phase of the signal, or both. Detection of the unbalance is a challenging problem especially for the phase unbalance, which cannot be detected by measuring and comparing the amplitudes of the three voltages. A detector with good performance for both amplitude and phase unbalance has yet to be developed.

Unbalance detection is an indicator of islanding. Islanding is a condition in which a distributed generation (DG) generator continues to power a location even though power from the grid is no longer present. During islanding, DGs should be immediately disconnected from the grid.

The unbalance of the voltage signal can be conventionally detected by monitoring several parameters of the signal, such as a magnitude of the amplitude, displacement of the phase, and changes in the frequency. However, those conventional methods may fail to detect small variation in the signal.

For example, one method uses a ratio of the magnitude of a negative sequence voltage Vₙ to the magnitude of a positive voltage sequence Vₚ, VU=|Vₙ|/|Vₚ|. However, that ratio is a suboptimal indicator. The magnitude of the negative sequence voltage |Vₙ| is typically much less than the magnitude of the positive sequence. Thus, the positive sequence dominates the ratio VU.

The ratio is not suitable to detect small unbalance conditions. If the threshold for permissible disturbance in these quantities is set to a low value, then nuisance grid disconnections become an issue. If the threshold is set too high, islanding may not be detected. Prior art techniques do not suggest an optimal threshold. For example, one method sets the threshold statically based on the average value of VU over the past one second, i.e., T_{b}=35VU_{avg}. However, that threshold is inaccurate, and often needs to be updated.

FIG. 1 shows a conventional unbalance detector 100. The detector acquires three phase voltage signals 111 at an input terminal 110. An analog to digital (A/D) converter 130 digitizes the voltage waveforms and produces a discrete signal 135. Then, an αβ transformation, also known as the Clarke transformation 140 is applied to transform the 3-channel signals 135 onto 2-channels 145 with a 90 degree phase difference. Positive and negative sequence voltage waveforms 155 are estimated 150.

Prior art techniques typically determine 180 the ratio VU 181 of the negative sequence voltage amplitude to the positive sequence voltage amplitude. The ratio 181 is monitored and compared 191 to a threshold. If the ratio 181 changes as much as the change coefficient 190 times the original value, then an unbalance is detected.

For example, one method sets the change coefficient to 35. Such a solution is very static and does not consider whether or how much the estimates are biased, and what the characteristics of the covariance of the estimates are. Therefore, the prior art approaches select heuristic thresholds and are subject to suboptimal performance.

Also, the conventional methods, such as the method described above, detect the unbalance of the signal that occurs within a portion of an observation window 101. This is because the observations of the signal in one part 103 of the observation window are compared with the observations of the signal from another part 102 of the observation window. Thus, if the frequency or voltage values of the signal remain fixed during the observation window, but are different from their nominal values, then the conventional methods fail to detect the unbalance. Also, such comparison often leads to increasing a size of the observation window, which is undesirable.

Accordingly there is a need to provide a system and a method for detecting an unbalance in a 3-phase voltage signal.

### SUMMARY OF THE INVENTION

It is an object of present invention to provide a system and a method for detecting an unbalance in a 3-phase voltage signal. It is another object of the invention to detect various degrees of the unbalances. It is further object of the invention to provide such a method that can detect the unbalance of the signal even based on a set of observations of unbalanced signal sampled over an entire observation window. It is further object of the invention to provide such a method that can detect the unbalance of the signal based on any deviation from nominal frequency, nominal phase and nominal voltage. It is further object of the invention to detect islanding condition of a power grid.

Embodiments of the invention are based on a realization that probability distribution of the observations of the signal sampled during the observation window can be used to detect the unbalance. This is because probability distributions of balanced and unbalanced signals have different means but similar covariances due to similarity of a noise component. For example, a likelihood ratio test can be used to compare whether the signal sampled during the observation window fit one of two models, one of which is a probability density function (pdf) of the balanced signal and the other is a pdf of an unbalanced signal.

Some embodiments use a ratio of joint pdf of the set of observations and a joint pdf of the signal without unbalance to detect the unbalance of the signal. For example, in one embodiment the unbalance detection problem is formulated as a parameter test, which is solved by using a generalized likelihood ratio test (GLRT). As used by this embodiment, the GLRT is a statistical test to compare the fit of two models, one of which is a model for the balanced case and the latter is a model for the unbalance case. The test is based on the likelihood ratio of these models.

For example, if the GLRT ratio is not equal to one, then the unbalance is detected. In one variation of this embodiment, the unbalance is detected if a difference between one and the ratio is greater than a threshold.

Accordingly, one embodiment of invention discloses a method for detecting unbalance in signal, wherein the signal is 3-phase voltage signal of a power grid. The method includes sampling the signal over an observation widow to determine a set of observations; and detecting the unbalance of the signal based on a probability density function (pdf) of the set of observations.

Another embodiment discloses an unbalance detector, comprising: an input terminal for acquiring a signal, wherein the signal is a 3-phase voltage; a statistical model computation module for determining a joint pdf of a set of observations of the signal; a processing unit for determining ratio of the joint pdf of the set of observations and a joint pdf of the signal without unbalance; a comparison module for comparing the ratio with a threshold to determine an unbalance of the signal; and an output terminal for signaling the unbalance of the signal.

Yet another embodiment discloses a method for detecting unbalance in a signal, wherein the signal is 3-phase voltage, the method comprising: determining a statistical value using a general likelihood ration test based on a set of samples of the signal and a frequency of the signal; and comparing the statistical value with a threshold to determine an unbalance of the signal, wherein the steps are performed by a processor.

### BRIEF DESCRIPTION OF THE DRAWINGS

FIG. 1 is a block diagram of a prior art unbalance detector;

FIG. 2 is a block diagram of a method for detecting unbalance in a 3-phase voltage signal according an embodiment of an invention;

FIG. 3 is a graph of probability distributions used by some embodiments of the invention;

FIG. 4 is a schematic of an unbalance detector according to one embodiment of the invention; and

FIGS. 5 and 6 are block diagrams of an unbalance detector according to various embodiments of the invention.

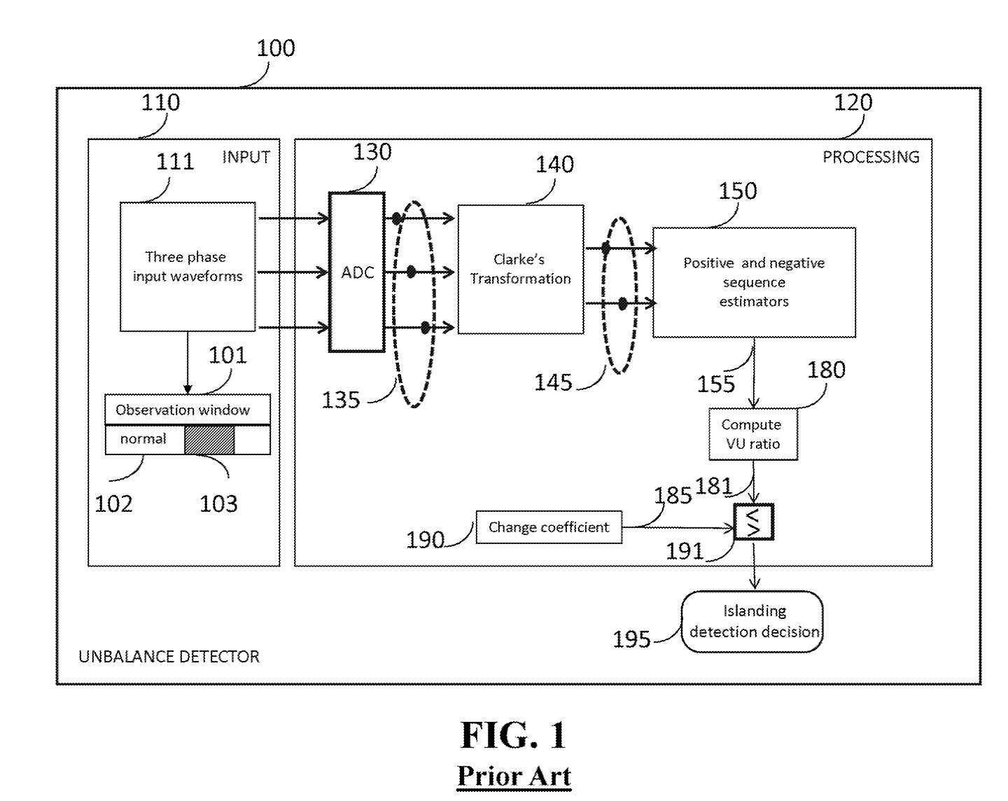

### DETAILED DESCRIPTION OF THE EMBODIMENTS

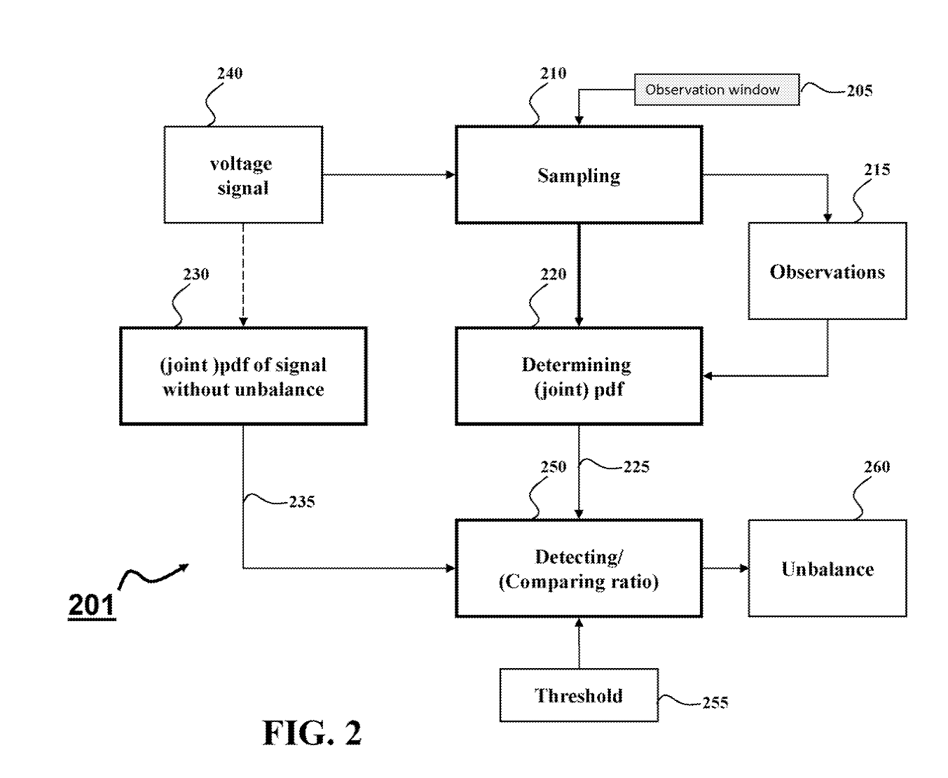

FIG. 2 shows a block diagram of a method for detecting unbalance in a 3-phase voltage signal. The method can be performed using a processor 201. The method includes sampling 210 the signal 240 during an observation widow 205 to determine a set of observations 215. In one embodiment, the set of observations represents the entire observation window. Next, a probability density function (pdf) 225 of the set of observations is determined 220 and the unbalance 260 of the signal is detected 250 based on that pdf. For example, in one embodiment, the set of observation or its pdf 225 is compared with a model of a balanced 3-phase voltage signal using, e.g., a likelihood ratio test.

In some embodiments, the unbalance is detected based on a joint pdf 225 of the set of observations. For example, in one embodiment the unbalance of the signal is based on comparing a ratio 250 of a joint pdf 225 of the set of observations and a joint pdf 235 determined 230 for the signal without unbalance.

In one embodiment, if the ratio is not equal to one, then the unbalance is detected. In some other embodiments, however, the ratio is compared with a threshold 255 to detect the unbalance. In one embodiment, the threshold is determined according to a desired probability of false alarm (PFA). For a higher PFA, the threshold is higher.

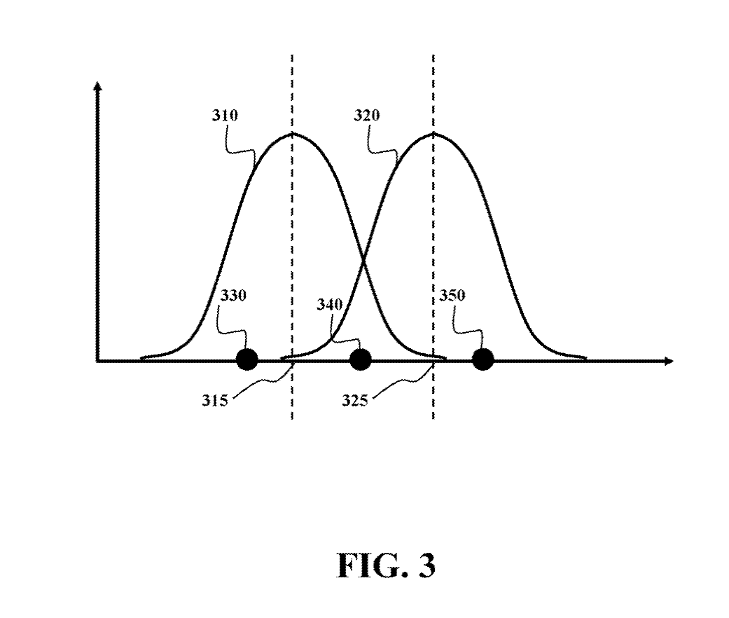

FIG. 3 shows the probability distributions used by some embodiments of the invention. Specifically, it is recognized that the probability distribution of the observations of the signal sampled during the observation window can be used to detect the unbalance, because the probability distributions 320 of balanced signal and the probability distributions 310 of unbalanced signals have similar covariances due to a similarity of the noise component, but different means 325 and 315, respectively.

Accordingly, the joint pdf determined based on the set of observation can be compared with the joint probability distributions 320 of balanced signal to detect the unbalance. If, for example, the joint pdf is dissimilar than the probability distributions 320 of balanced signal, e.g., a point 330, then the unbalance can be detected. If the joint pdf is similar to the probability distributions 320 of balanced signal, e.g., a point 350, then the balance can be detected.

If, however, the joint pdf is at a point 340, such that the point is likely to be from either model, some embodiments use various statistical tests, e.g., the likelihood ratio test, to compare whether the observations of the signal sampled during the observation window fit one of two statistical models of balanced and unbalanced signal. In some variations of this embodiment, the statistical models are parameterized probability density functions.

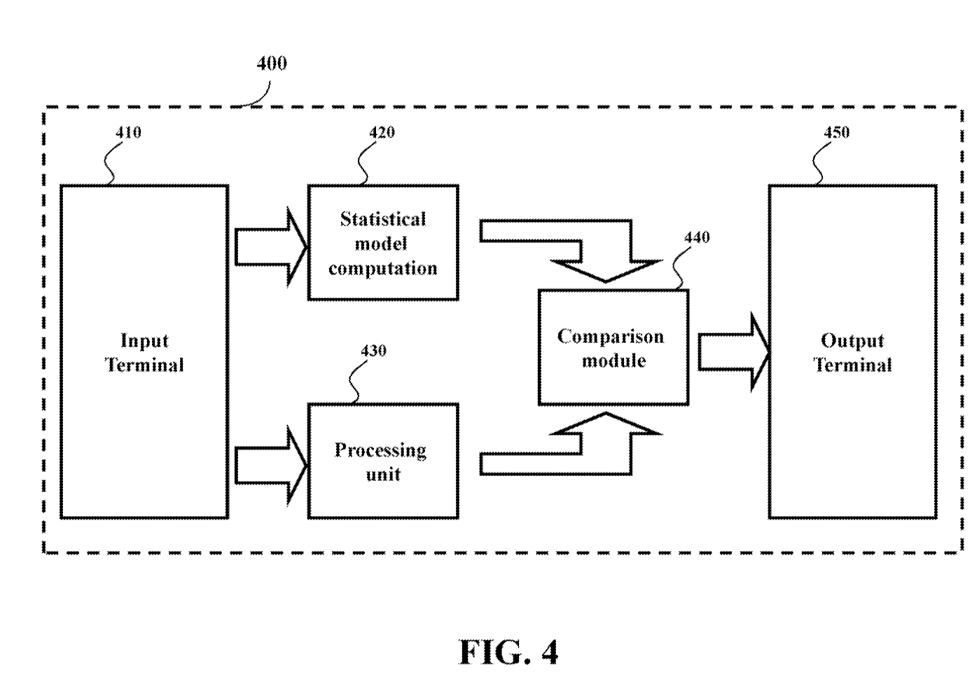

FIG. 4 shows an unbalance detector 400 according to one embodiment of the invention. The unbalance detector includes an input terminal 410 for acquiring a 3-phase voltage signal. The 3-phase voltage signal can be used for both determining the joint pdf of balanced signal and the joint pdf of the set of observations. For example, the unbalance detector includes a statistical model computation module 420 for determining the joint pdfs, and a processing unit 430 for determining ratio of a joint pdf of the set of observations and a joint pdf of the signal without unbalance.

Also, the detector includes a comparison module 440 for comparing the ratio with the threshold to determine an unbalance of the voltage signal, and an output terminal 450 for signaling the unbalance of the voltage signal. Various modules and units of the unbalance detector can be implemented using a processor. The input terminal can be connected to the power grid. The output terminal can be implemented using any type of signaling mechanism, including signaling with light or sound, transmitting messages, or cause an execution of a computer implemented program.

Various embodiments may be implemented using hardware, software or a combination thereof. When implemented in software, the software code can be executed on any suitable processor or collection of processors, whether provided in a single computer or distributed among multiple computers. Such processors may be implemented as integrated circuits, with one or more processors in an integrated circuit component. Though, a processor may be implemented using circuitry in any suitable format.

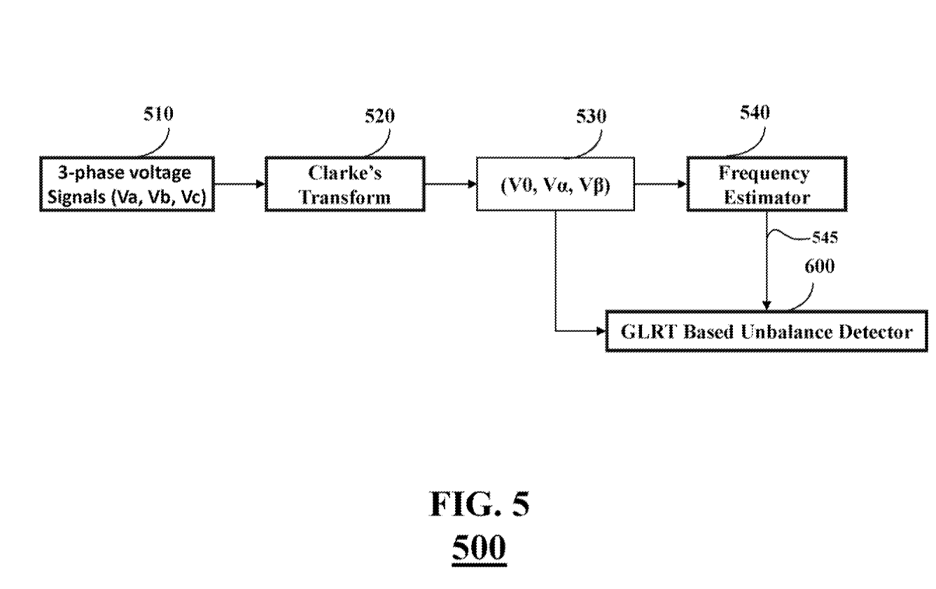

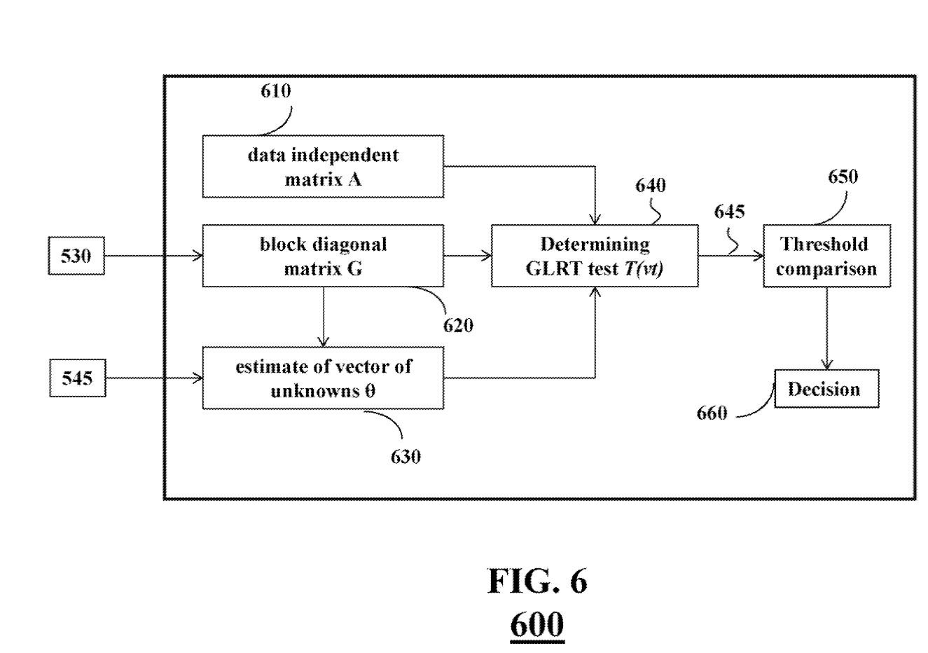

FIGS. 5 and 6 show an example of unbalance detector 500 including general likelihood ration test (GLRT) based unbalanced detector 600 according to one embodiment of the invention. This example serves to illustrate the method for detecting unbalance of the signal, and not intended to limit the scope of the invention.

Input 510 to the unbalance detector 500 includes 3-phase voltage signals 511 from the power grid. The discrete 3-phase voltage signals 535 corrupted by additive noise are expressed as

vₐ(n)=Vₐ cos(nw+φₐ)+eₐ(n)

v_{b}(n)=V_{b} cos(nw+φ_{b})+e_{b}(n)

v_{c}(n)=V_{c} cos(nw+φ_{c})+e_{c}(n) (1)

where n is a discrete time index, for i=a, b, c, Vᵢ is the amplitude and φᵢ is an initial phase angle of the phase i, and w is an angular frequency of the power grid given by W=2πf/fₛ, where f and fₛ are the grid frequency and the sampling frequency, respectively, and e is Gaussian distributed additive noise with zero mean. The additive noise can be caused by the analog-to-digital converter circuit, or the noise may be already present in the signal.

The additive noise vector at time instant n is

e(n)=[eₐ(n),e_{b}(n),e_{c}(n)]^{T},

where T is a transpose operator. The noise is assumed to be a zero-mean Gaussian random vector with a covariance matrix Q. The noise vectors at different time instants are uncorrelated.

According to Fortescue's theorem, the 3-phase grid voltage signals 535 in vector form can be rewritten as

v(n)=vₚ(n)+vₙ(n)+v₀(n)+e(n),

where vₚ(n), vₙ(n) and v₀(n) represent the positive, negative and zero sequences respectively and defined by

$${v}_{p} ( n ) = {{V}_{p} [ cos {θ}_{p} ( n ) , cos ( {θ}_{p} ( n ) - \frac{2 π}{3} ) , cos ( {θ}_{p} ( n ) + \frac{2 π}{3} ) ]}^{T} \\ {v}_{n} ( n ) = {{V}_{n} [ cos {θ}_{n} ( n ) , cos ( {θ}_{n} ( n ) + \frac{2 π}{3} ) , cos ( {θ}_{n} ( n ) - \frac{2 π}{3} ) ]}^{T} \\ {v}_{0} ( n ) = {{V}_{0} [ cos {θ}_{0} ( n ) , cos {θ}_{0} ( n ) , cos {θ}_{0} ( n ) ]}^{T} , \qquad ( 2 )$$

where Vᵢ and θᵢ(n) for i=p, n, 0 are the amplitude and phase angle of each sequence, respectively.

Clarke Transformation

Some embodiments apply the Clarke transformation 520 to the 3-phase voltage signals described by Equation (1) to determine corresponding αβ-reference frame signals 530 as

[v_{α}(n),v_{β}(n)]^{T}=T[vₐ(n),v_{b}(n),v_{c}(n)]^{T}, (3)

where

$$T = \frac{2}{3} [ \begin{matrix}1 & - \frac{1}{2} & - \frac{1}{2} \\ 0 & \frac{\sqrt{3}}{2} & - \frac{\sqrt{3}}{2}\end{matrix} ]$$

is a Clarke transformation matrix.

The resulting αβ-reference frame signals 530 can be rewritten as

$$[ \begin{matrix}{v}_{α} ( n ) \\ {v}_{β} ( n )\end{matrix} ] = {V}_{p} [ \begin{matrix}cos {θ}_{p} ( n ) \\ sin {θ}_{p} ( n )\end{matrix} ] + {V}_{n} [ \begin{matrix}cos {θ}_{n} ( n ) \\ - sin {θ}_{n} ( n )\end{matrix} ] + [ \begin{matrix}{e}_{α} ( n ) \\ {e}_{β} ( n )\end{matrix} ] . \qquad ( 4 )$$

The covariance of the noise vector at the output of the Clarke transformation e_{αβ}(n)=[e_{α}(n),e_{β}(n)]^{T} is

Q_{αβ}=TQT^{T}

The Clarke transformation is beneficial because the zero sequence is canceled, and the number of unknown parameters is reduced by two. Although the number of unknown parameters in Equation (4) is reduced, Equation (4) is still difficult to solve because the equation includes two sinusoidal signals and is highly non-linear with respect to unknown parameters.

However, based on the fact that θₚ(n) and θₙ(n) have the same frequency, Equation (4) can be rewritten as

$$\begin{matrix}{v}_{α} ( n ) = ( {V}_{p} cos {ϕ}_{p} + {V}_{n} cos {ϕ}_{n} ) cos ( nw ) - \\ ( {V}_{p} sin {ϕ}_{p} + {V}_{n} sin {ϕ}_{n} ) sin ( nw ) + {e}_{a} ( n ) \\ = {V}_{α} cos ( nw + {ϕ}_{α} ) + {e}_{α} ( n )\end{matrix} \\ \begin{matrix}{v}_{β} ( n ) = ( {V}_{p} sin {ϕ}_{p} - {V}_{n} sin {ϕ}_{n} ) cos ( nw ) - \\ ( - {V}_{p} cos {ϕ}_{p} + {V}_{n} cos {ϕ}_{n} ) sin ( nw ) + {e}_{β} ( n ) \\ = {V}_{β} cos ( nw + {ϕ}_{β} ) + {e}_{β} ( n ) .\end{matrix} \qquad ( 5 )$$

It can be seen from Equation (5) that each phase in the αβ domain includes only one noise corrupted sinusoidal signal. The problem becomes estimating parameters of a single-tone sinusoidal signal.

Grid Frequency Estimator

One embodiment includes a frequency estimator 540 to estimate of a grid frequency 545. Any sinusoidal frequency estimators can be used by the detector 500 for estimating the frequency. One embodiment uses unbiased frequency estimator 550 is unbiased. The frequency estimate 555 is denoted as w.

GLRT Based Unbalance Detector

As shown in FIG. 6 for the grid frequency estimate 545, some embodiments determine the unbalance using a general likelihood ration test. In one embodiment, the GLRT based unbalance detector 600 receives the grid frequency estimate 545 and the Clarke transform output signal 530 as inputs and determines a data independent matrix A 610, and a block diagonal matrix G 620. The detector uses a block diagonal matrix G and the transform an output signal v, to determine an estimate of a vector of unknowns 630 according to

\hat{θ}₁=(G^{T}G)⁻¹G^{T}vₜ

wherein superscript T is a transpose operator.

Then, the detector determines 640 a statistical value 645 of the GLRT, e.g., the ratio. The statistical value is compared 650 with a threshold to make an unbalance decision 660. For example, if the test statistic value T(vₜ) is greater than the threshold, then an unbalance is determined. In one embodiment, the threshold is selected based on a probability of a false alarm. In various embodiments, the detector 600 is implemented using a processor 601.

For example, the vector of unknowns θ 630 is defined as

θ=[θᵣ^{T},θₛ^{T}]^{T}, where vectors

θᵣ=[v₀ cos φ₀V₀ sin φ₀Vₙ cos φₙVₙ sin φₙ]^{T} (7)

and

θₐ=[Vₚ cos φₚVₚ sin φₚ]^{T} (8)

wherein V₀ is the amplitude of the zero sequence voltage, Vₚ is the amplitude of the positive sequence voltage, Vₙ is the amplitude of the negative sequence voltage, φ₀ is the initial phase angle of the zero sequence signal, φₚ is the phase angle of the positive sequence signal and φ₀ is the phase angle of the negative sequence signal, θᵣ is the parameter of interest and θₛ is the general parameter vector with nuisance parameters.

Given the data from the Clarke transform output signal

vₜ(n)=[v₀(n),v_{α}(n),v_{β}(n)]^{T}₅₃₀,

where n is an observation from the set of observation of a size N, n=1 . . . N, and the GLRT based test becomes the parameter test according to

H₀:θᵣ=0,θₛ,

H₁:θᵣ≠0,θₐ. (9)

Given the estimate of the grid frequency 545, the GLRT test according one embodiment is

$${L}_{G} ( {v}_{t} ) = \frac{{p}_{1} ( {v}_{t} ; {\hat{θ}}_{r 1} , {\hat{θ}}_{s 1} , ω )}{{p}_{0} ( {v}_{t} ; {\hat{θ}}_{s 0} , ω )} , \qquad ( 10 )$$

where p₀ is the likelihood function under hypothises H₀, p₁ is the likelihood function under hypothises H₁, \hat{θ}₁=[\hat{θ}ᵣ₁^{T},\hat{θ}ₛ₁^{T}]^{T} is the maximum likelihood estimate of the vector θ=[θᵣ θₛ] and \hat{θ}ₛ₀ is the maximum likelihood estimator (MLE) of the vector θₛ under hypothises H₀ having θᵣ=0.

The Equation (6) describes a linear model with respect to the unknown vector θ=[θᵣ θₛ] given the grid frequency estimate. The linear model is given by

vₜ=Gθ+eₜ (11)

where eₜ=[eₜ^{T}(0), eₜ^{T}(1), . . . , eₜ^{T}(N−1)]^{T} is a composite noise vector with a covariance matrix ⅔σ²I, I is an identity matrix with its diagonal elements 1 and all others zero, G=[G₀^{T}, G₁^{T}, . . . , G_{N-1}^{T}]^{T} is the block diagonal matrix 620 and Gₙ is a block diagonal matrix

$${G}_{n} = diag ( {G}_{n , 1} , {G}_{n , 2} ) , where$$

$${G}_{n , 1} = [ \begin{matrix}\sqrt{2} cos ( n ω ) & - \sqrt{2} sin ( n ω )\end{matrix} ] and$$

$${G}_{n , 2} = [ \begin{matrix}cos ( n ω ) & - sin ( n ω ) & cos ( n ω ) & - sin ( n ω ) \\ - sin ( n ω ) & - cos ( n ω ) & sin ( n ω ) & cos ( n ω )\end{matrix} ] .$$

Accordingly, the unbalance decition problem is

H₀:Aθ=0,

H₁:Aθ≠0, (12)

where A=[I_{4×4}, O_{4×2}] is the data independent matrix 610.

The statistical value of the GLRT can be determined according to

$$\begin{matrix}T ( {v}_{t} ) = 2 ln {L}_{G} ( {v}_{t} ) \\ = \frac{{\hat{θ}}_{1}^{T} {{A}^{T} ( {A ( {G}^{T} G )}^{- 1} {A}^{T} )}^{- 1} A {\hat{θ}}_{1}}{2 {σ}^{2} / 3}\end{matrix} \qquad ( 13 )$$

where \hat{θ}₁=(G^{T}G)⁻¹G^{T}vₜ the MLE of θ 410 under hypothesis

The above-described embodiments of the present invention can be implemented in any of numerous ways. For example, the embodiments may be implemented using hardware, software or a combination thereof. When implemented in software, the software code can be executed on any suitable processor or collection of processors, whether provided in a single computer or distributed among multiple computers. Such processors may be implemented as integrated circuits, with one or more processors in an integrated circuit component. Though, a processor may be implemented using circuitry in any suitable format.

Further, it should be appreciated that a computer may be embodied in any of a number of forms, such as a rack-mounted computer, a desktop computer, a laptop computer, minicomputer, or a tablet computer. Such computers may be interconnected by one or more networks in any suitable form, including as a local area network or a wide area network, such as an enterprise network or the Internet. Also, the various methods or processes outlined herein may be coded as software that is executable on one or more processors that employ any one of a variety of operating systems or platforms. In this respect, the invention may be embodied as a computer readable storage medium or multiple computer readable media.

Although the invention has been described by way of examples of preferred embodiments, it is to be understood that various other adaptations and modifications can be made within the spirit and scope of the invention. Therefore, it is the object of the appended claims to cover all such variations and modifications as come within the true spirit and scope of the invention.

We claim:

1. A method for detecting unbalance in signal, wherein the signal is 3-phase voltage signal of a power grid, the method comprising:
sampling the signal over an observation window to determine a set of observations; and
detecting the unbalance of the signal based on a probability density function (pdf) of the set of observations.

2. The method of claim 1, wherein the detecting further comprises:
determining the unbalance of the signal based on a joint pdf of the set of observations.

3. The method of claim 1, wherein the detecting further comprises:
determining the unbalance of the signal based on a ratio of a joint pdf of the set of observations and a joint pdf of the signal without unbalance.

4. The method of claim 1, wherein the signal is
vₐ(n)=Vₐ cos(nw+φₐ)+eₐ(n)
v_{b}(n)=V_{b} cos(nw+φ_{b})+e_{b}(n)
v_{c}(n)=V_{c} cos(nw+φ_{c})+e_{c}(n)
where n is an instant in time for i=a, b, c, Vᵢ is an amplitude, φᵢ is an initial phase angle of the phase i, w is an angular frequency of the power grid given by w=2πf/fₛ where f and fₛ are a grid frequency and a sampling frequency, respectively, e is additive noise, wherein the additive noise vector at time instant n is
e(n)=[eₐ(n),e_{b}(n),e_{c}(n)]^{T},
and T is a transpose operator.

5. The method of claim 4, wherein the signal is represented by a vector
v(n)=vₚ(n)+vₙ(n)+v₀(n)+e(n),
where vₚ(n), vₙ(n) and v₀(n) represent a positive sequence, a negative sequence, and a zero sequence.

6. The method of claim 5, further comprising:
transforming the signal to an αβ-reference frame signals using a Clark transformation matrix; and
determining the unbalance indicator based on the αβ-reference frame signals and an estimation of a frequency of the signal.

7. The method of claim 6, wherein the Clarke transformation matrix is
$$T = \frac{2}{3} [ \begin{matrix}1 & - \frac{1}{2} & - \frac{1}{2} \\ 0 & \frac{\sqrt{3}}{2} & - \frac{\sqrt{3}}{2}\end{matrix} ] ,$$
and the αβ-reference frame signal is represented by
$$y ( n ) = [ \begin{matrix}{v}_{α} ( n ) \\ {v}_{β} ( n )\end{matrix} ] = {V}_{p} [ \begin{matrix}cos {θ}_{p} ( n ) \\ sin {θ}_{p} ( n )\end{matrix} ] + {V}_{n} [ \begin{matrix}cos {θ}_{n} ( n ) \\ - sin {θ}_{n} ( n )\end{matrix} ] + [ \begin{matrix}{e}_{α} ( n ) \\ {e}_{β} ( n )\end{matrix} ] ,$$
wherein Vᵢ and θᵢ(n) for i=p, n, 0 are an amplitude and a phase angle of each sequence, respectively.

8. The method of claim 6, further comprising:
determining a statistical value using a general likelihood ratio test based on the αβ-reference frame signals and the frequency of the voltage signal; and
detecting the unbalance based on the statistical value.

9. The method of claim 8, further comprising:
acquiring a data independent matrix A;
determining a block diagonal matrix G;
determining an estimate of a vector of unknowns; and
determining the statistical value based on the matrix A, the matrix G, and the vector of unknowns.

10. The method of claim 8, further comprising:
determining the statistical value T(vₜ) according to
$$T ( {v}_{t} ) = \frac{{\hat{θ}}_{1}^{T} {{A}^{T} ( {A ( {G}^{T} G )}^{- 1} {A}^{T} )}^{- 1} A {\hat{θ}}_{1}}{2 {σ}^{2} / 3} ,$$
wherein the matrix A is pre-determined according to A=[I_{4×4}, O_{4×2}], the matrix G is a block diagonal matrix which is a function of the fundamental frequency w, σ² is the variance of noise and \hat{θ}₁ is the estimate of the vector of unknowns.

11. The method of claim 1, further comprising:
comparing the set of observation with a model of a balanced 3-phase voltage signal using a likelihood ratio test, wherein the set of observations represents the entire observation window.

12. An unbalance detector, comprising:
an input terminal for acquiring a signal, wherein the signal is a 3-phase voltage;
a statistical model computation module for determining a joint pdf of a set of observations of the signal;
a processing unit for determining ratio of the joint pdf of the set of observations and a joint pdf of the signal without unbalance;
a comparison module for comparing the ratio with a threshold to determine an unbalance of the signal; and
an output terminal for signaling the unbalance of the signal.

13. The detector of claim 12, wherein the ratio is determined as a statistical value T(vₜ) of a general likelihood ration test according to
$$T ( {v}_{t} ) = \frac{{\hat{θ}}_{1}^{T} {{A}^{T} ( {A ( {G}^{T} G )}^{- 1} {A}^{T} )}^{- 1} A {\hat{θ}}_{1}}{2 {σ}^{2} / 3} ,$$
wherein the matrix A is pre-determined according to A=[I_{4×4}, O_{4×2}], the matrix G is a block diagonal matrix which is a function of the fundamental frequency w, σ² is the variance of noise and \hat{θ}₁ is the estimate of the vector of unknowns.

14. A method for detecting unbalance in a signal, wherein the signal is 3-phase voltage, the method comprising:
determining a statistical value using a general likelihood ratio test based on a set of samples of the signal and a frequency of the signal; and
comparing the statistical value with a threshold to determine an unbalance of the signal, wherein the steps are performed by a processor.

15. The method of claim 16, further comprising:
determining the threshold based on a probability of a false alarm.

16. The method of claim 17, wherein the probability of the false alarm includes a probability of detecting unbalance in a balanced signal.

17. The method of claim 16, further comprising:
determining an islanding condition based on the unbalance.
